(19) United States
(12) Patent Application Publication
(10) Pub. No.: US 2025/0293100 A1
(43) Pub. Date: Sep. 18, 2025

(54) MANUFACTURING METHOD FOR SEMICONDUCTOR DEVICE AND SEMICONDUCTOR WAFERS

(71) Applicant: RENESAS ELECTRONICS CORPORATION, Tokyo (JP)

(72) Inventors: Atsushi AMO, Tokyo (JP); Hiraku CHAKIHARA, Tokyo (JP); Hiroshi YANAGITA, Tokyo (JP); Akio ONO, Tokyo (JP)

(21) Appl. No.: 19/225,869

(22) Filed: Jun. 2, 2025

Related U.S. Application Data
(62) Division of application No. 17/876,067, filed on Jul. 28, 2022.

(30) Foreign Application Priority Data
Sep. 17, 2021 (JP) 2021-151960

(51) Int. Cl. H01L 21/66; H10B 10/00; H10D 62/10; H10D 64/01; H10D 64/27; H10D 64/68

(52) U.S. Cl. CPC H01L 22/34; H01L 22/14; H10B 10/12; H10D 62/102; H10D 64/01; H10D 64/514; H10D 64/685; H10D 64/693

(57) ABSTRACT

A method of manufacturing a semiconductor device capable of detecting occurrence of a Hi-K disappearance is provided. The method of manufacturing a semiconductor device includes a step of manufacturing a test pattern including a reference resistance, a gate leakage resistance through which a gate leakage current flows and connected in series with the reference resistance, and a step of measuring a change in voltage at a connection node between the reference resistance and the gate leakage resistance caused by the flow of the gate leakage current.

### CROSS-REFERENCE TO RELATED APPLICATION

This application is a Divisional of U.S. patent application Ser. No. 17/876, 067, filed on Jul. 28, 2022, which claims the benefit of foreign priority to Japanese Patent Application No. 2021-151960 filed on Sep. 17, 2021, the entire contents of each of which are hereby incorporated by reference.

### BACKGROUND

The present invention relates to a method of manufacturing a semiconductor device and a semiconductor wafer, for example, a method of manufacturing a semiconductor device using an insulating film having a dielectric constant higher than a silicon nitride film as a gate insulating film (hereinafter, referred to as a transistor or FET) is formed and a semiconductor wafer.

There is disclosed techniques listed below.

[Patent Document 1] Japanese Unexamined Patent Application Publication No. 2021-27096

An FET using a high-dielectric-constant insulating film having a higher dielectric constant than a silicon nitride film as a gate insulating film is described in, for example, Patent Document 1. Patent Document 1 describes a technique related to a manufacturing method of a semiconductor device capable of improving reliability.

### SUMMARY

With the advance of semiconductor devices, the refinement of FETs advances, and the thinning of gate insulator film of FET advances. When thinning the gate insulating film, is conceivable that the gate leakage current flowing through the gate insulating film is increased, for example, to reduce the gate leakage current, and, as a gate insulating film, for example, a high dielectric constant insulating material having a higher dielectric constant than the silicon nitride film (Hi-K) it has been used.

A gate insulating film of Hi-K is constituted by, for example, a hafnium oxide (HfO₂) film. In Patent Document 1, on this a hafnium oxide film, a titanium nitride (TiN) layer of dielectric to stop etching is formed. Such a hafnium oxide film and a titanium nitride layer stacked thereon may disappear due to, for example, a variation in a process of manufacturing a semiconductor device. Hereinafter, disappearance of the hafnium oxide film and the titanium nitride layer stacked thereon is referred to as Hi-K disappearance.

When the Hi-K disappearance occurs, for example, the gate leakage current is increased, and thus the transistor characteristics of the FETs are not the desired characteristics, and the circuitry in the semiconductor device may not operate normally.

In Patent Document 1, neither recognizing nor describing Hi-K disappearance described above.

A brief summary of representative of the embodiments disclosed in the present application will be described below.

That is, a method of manufacturing a semiconductor device according to an embodiment includes a step of forming a test pattern including a reference resistance and a gate leakage resistance connected in series with the reference resistance and through which the gate leakage current flows, and a method of measuring a change in voltage at a connection node between the reference resistance and the gate leakage resistance caused by the flow of the gate leakage current.

Other problems and novel features will become apparent from the description herein and from the accompanying drawings.

According to an embodiment of the present invention, there can be provided a method of manufacturing a semiconductor device capable of detecting the occurrence of Hi-K disappearance.

### BRIEF DESCRIPTIONS OF THE DRAWINGS

FIG. 1A is a plan view schematically illustrating a configuration of a semiconductor wafer according to a first embodiment.

FIG. 1B is a plan view schematically illustrating a configuration of the semiconductor wafer according to the first embodiment.

FIG. 2 is a flowchart schematically illustrating a method of manufacturing a semiconductor wafer according to the first embodiment.

FIG. 3 is a plan view schematically illustrating a configuration of a semiconductor chip and a TEG circuit according to the first embodiment.

FIG. 4 is a circuit diagram illustrating a configuration of a memory cell.

FIG. 5A is a cross-sectional view for explaining a semiconductor device according to the first embodiment.

FIG. 5B is a cross-sectional view for explaining the semiconductor device according to the first embodiment.

FIG. 6 is a plan view illustrating a configuration of a test pattern according to the first embodiment.

FIG. 7 is a schematic plan view illustrating a configuration of a reference resistance according to the first embodiment.

FIG. 8 is a schematic sectional view illustrating the relationship between the reference resistance and the test pattern according to the first embodiment.

FIG. 9A is a diagram for explaining a TEG circuit according to the first embodiment.

FIG. 9B is a diagram for explaining the TEG circuit according to the first embodiment.

FIG. 10A is a diagram for explaining a TEG circuit according to a first modification of the first embodiment.

FIG. 10B is a diagram for explaining the TEG circuit according to a first modification of the first embodiment.

FIG. 11 is a block diagram illustrating a configuration of a TEG circuit according to a second modification of the first embodiment.

FIG. 12 is a diagram for explaining gate leakage current and gate leakage resistance according to the first embodiment.

FIG. 13A is a diagram for explaining an effect according to the first embodiment.

FIG. 13B is a diagram for explaining an effect according to the first embodiment.

FIG. 14 is a diagram for explaining a manufacturing process of a semiconductor device according to a second embodiment.

FIG. 15 is a diagram for explaining a manufacturing process of a semiconductor device according to a third embodiment.

FIG. 16 is a diagram for explaining a method of manufacturing a semiconductor device according to the third embodiment.

### DETAILED DESCRIPTION

Embodiments of the present invention will be described below with reference to the drawings. It is to be noted that the disclosure is merely an example, and appropriate changes which those skilled in the art can easily conceive of while maintaining the gist of the invention are naturally included in the scope of the invention.

In the present specification and each drawing, the same reference numerals are assigned to the same elements as those described above with reference to the preceding drawings, and detailed description thereof may be omitted as appropriate.

In the following, as an example of a semiconductor device, a semiconductor wafer in which a plurality of semiconductor chips and a test pattern (hereinafter, also referred to as TEG (Test Elementary Group) circuit) are arranged will be described, and also a semiconductor chip on which TEG circuit and a plurality of circuit blocks are arranged may be a semiconductor device.

### First Embodiment

### Method of Manufacturing a Semiconductor Wafer and a Semiconductor Device

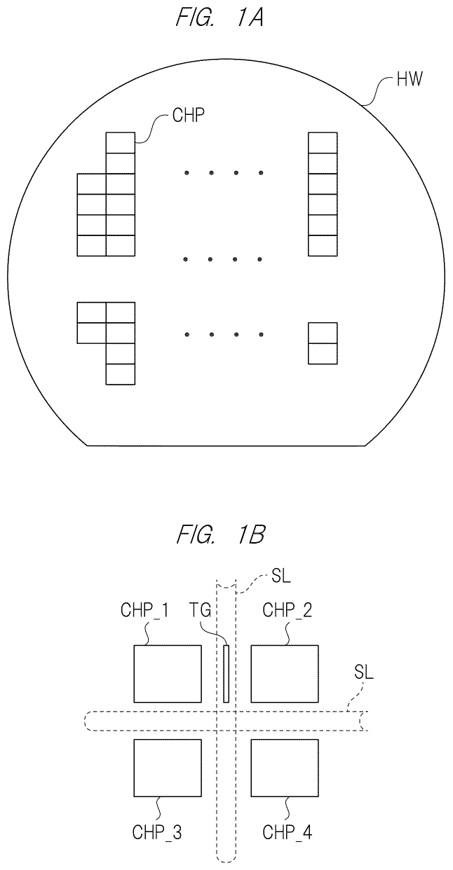

FIG. 1 is a plan view schematically illustrating a configuration of a semiconductor wafer according to a first embodiment. Here, FIG. 1A is a plan view of the semiconductor wafer, FIG. 1B is a plan view illustrating an arrangement of a semiconductor chip and a TEG circuit in the semiconductor wafer. In FIG. 1A, HW indicates a semiconductor wafer. As shown in FIG. 1A, the semiconductor wafer HW, a plurality of semiconductor chips CHP are formed. In FIG. 1B, TG indicates the TEG circuit. The TEG circuit TG is formed between, for example, two semiconductor chips CHP_1 and CHP_2 in the semiconductor wafer HW.

In the TEG circuit TG, parts similar to the components such as FETs formed on the semiconductor chip CHP are formed. Characteristics and the like of the components TEG circuit TG are measured, and the characteristics of the components semiconductor chip CHP is provided is estimated. In FIG. 1B, a broken line SL indicates a scribe line for cutting out the semiconductor chips CHP_1 to CHP_4 from the semiconductor wafer HW.

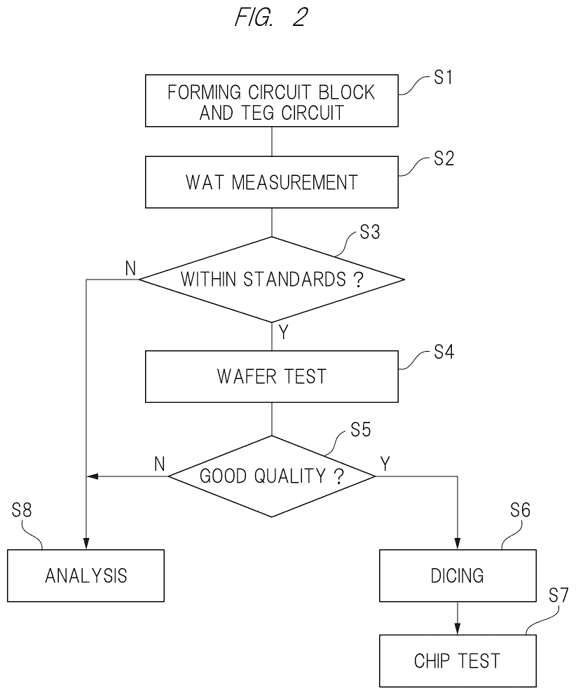

FIG. 2 is a flowchart diagram schematically illustrating a method of manufacturing a semiconductor wafer (semiconductor device) according to the first embodiment. In FIG. 2, according to the semiconductor manufacturing technique, S1 illustrates a step of forming a wiring layer or the like for connecting the components and components of the circuit block and TEG circuit to the semiconductor wafer HW. S2 represents a wafer acceptance test (Wafer Acceptance Test) process (hereinafter also referred to as WAT). In the WAT process, characteristics of components, for example, FETs, in the TEG circuit formed in the forming process S1 are measured. Whether or not the measured FET characteristic is within a predetermined standard is determined in the determination step S3. The semiconductor wafer HW which is determined (Y) that the characteristics of the FET is present within a predetermined standard, and in the wafer test step S4, the test of the semiconductor wafer HW is performed. Based on the test results in the wafer test step S4, in step S5, it is determined whether the semiconductor wafer is non-defective is performed.

In the decision step S5, if it is determined that the good (Y), in step S6, dicing along the scribe line SL (FIG. 1B) is performed, and from the semiconductor wafer HW (FIG. 1A), the semiconductor chip CHP is cut out. The cut-out semiconductor chip CHP is packaged, for example, and in the chip test step S7, the chip test is performed.

The product selected as a non-defective product by the chip test is shipped. That is, from each semiconductor wafer HW, so that a plurality of semiconductor chips CHP is manufactured.

On the other hand, when it is determined (N) that the characteristics of the FET do not exist within the predetermined standard (out of the standard) in the determination step S3, or when it is determined (N) that the FET is not a non-defective product in the determination step S5, the semiconductor wafer HW is not diced and a step S8 is performed. In the step S8, including a semiconductor wafer HW determined not to be out of specification or non-defective, for example, with respect to the lot, analysis or the like of the characteristics of the parts formed in the semiconductor wafer is performed.

As will be described later, in the embodiment, in the WAT step S2, the gate leakage current of the FET is measured with high sensitivity. As a predetermined standard value to be applied in the determination step S3, by defining the value of the gate leakage current, it is possible to determine the good/defective of the semiconductor wafer HW according to the value of the gate leakage current measured.

In the determination step S3, rather than determining the good/defective semiconductor wafer HW based on the gate leakage current, when the gate leakage current is large, for example, as a defective sign, it may be notified to the subsequent test step (e.g., wafer test step S4, determination step S5). In this case, the gate leakage current measured in the WAT step S2 will be used as an alert alarm in subsequent test steps performed on the same semiconductor wafer.

In the first embodiment, as shown in FIG. 1B, since the TEG circuit TG is disposed in the scribe line SL is removed from the semiconductor chip CHP by dicing is performed in step S6. However, the TEG circuit TG may be disposed at a position outside the scribe line SL. In this case, in the semiconductor chip CHP, a portion of the TEG circuit TG or TEG circuit TG remains.

### Semiconductor Chip

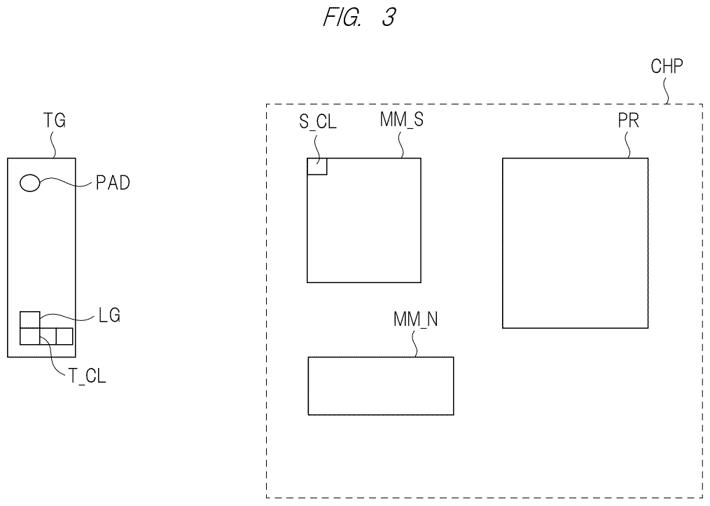

FIG. 3 is a plan view schematically illustrating the configuration of a semiconductor chip and TEG circuit according to the first embodiment.

The semiconductor chip CHP according to the first embodiment, although a plurality of circuit blocks are formed, only the circuit block necessary for description is shown in FIG. In FIG. 3, MM_S represents a static type memory (hereinafter also referred to as a SRAM circuit) which is an electrically volatile memory, MM_N represents an electrically erasable nonvolatile memory, and PR represents circuit blocks formed by combining a plurality of logic circuits. For the circuit block PR

For example, a processor that operates in accordance with a program stored in the non-volatile memory MM_N is configured. The SRAM circuit MM_S includes a plurality of static memory cells (hereinafter, also referred to as memory cells) S_CL, and temporarily stores data when the processor operates, for example. The nonvolatile memory MM_N includes, for example, a plurality of N-channel MONOS (Metal Oxide Nitride Oxide Silicon) transistors having charge-storage layers, and the MONOS transistor stores program data.

In the TEG circuit TG, a plurality of test patterns corresponding to a plurality of parts, and an electrode (pad) to which the probe is abutted during WAT measurement is formed. FIG. 3 illustrates, as test patterns, a plurality of test patterns T_CL having the same configuration as that of the memory cell S_CL, and a logic circuit LG connected to the plurality of test patterns T_CL. Further, in FIG. 3, a pad to which the logic circuit LG is connected is shown as a pad PAD.

In the following, a case in which the FET comprising the test pattern T_CL of the memory cell detects whether or not a Hi-K disappearance has occurred will be described as an example. First, the configuration of the memory cell S_CL will be described.

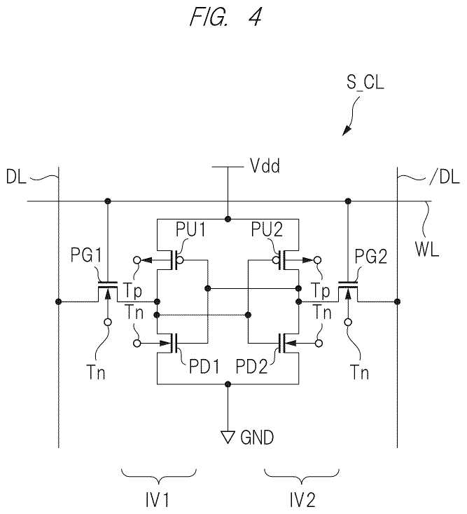

FIG. 4 is a circuit diagram illustrating a configuration of a memory cell. The memory cell S_CL includes an N-channel FETs (hereinafter also referred to as N-FETs) PD1, PD2, and PG1, PG2 and a P-channel FET (hereinafter also referred to as P-FET) PU1 and PU2. The drain region of the N-FET PD1 is connected to the drain region of the P-FET PU1, the source region is connected to the ground voltage GND, and the gate electrode is connected to the gate electrode of the P-FET PU1. The source area of the P-FET PU1 is connected to a power supply Vdd. Similarly, the drain region of the N-FET PD2 is connected to the drain region of the P-FET PU2, the source region is connected to the ground voltage GND, and the gate electrode is connected to the gate electrode of the P-FET PU2. The source area of the P-FET PU2 is connected to a power supply Vdd.

The gate electrodes of the FETs PU1 and, PD1 are connected to the drain regions of the FETs PU2 and PD2. The gate electrodes of the FETs PU2 and PD2 are connected to the drain regions of the FETs PU1 and PD1. That is, the CMOS inverter IV1 configured by the FETs PU1 and PD1, and the CMOS inverter IV2 configured by the FETs PU2 and PD2 are cross-connected, so that a latching circuit is configured. Between the output of the CMOS inverter IV1 (input of CMOS inverter IV2) and the bit line DL, the path of the drain region and source region of the N-FET PG1 is connected in series, the gate electrode of the N-FET PG1 is connected to the word line WL. Further, between the output of CMOS inverter IV2 (input of CMOS inverter IV1) and the bit line/DL, the path of the drain region and the source region of the N-FET PG2 is connected in series, and the gate electrode of the N-FET PG2 is connected to the word line WL.

In FIG. 4, the arrows described in the N-FETs PD1, PD2, PG1, and PG2 indicate the gate of the substrate side of the N-FET (back gate), and the terminal In connected to the back gate indicates the electrode of the substrate side. Similarly, the arrows in the P-FETs PU1 and PU2 indicate the back-gate of the P-FET, and the terminals Tp connected to the back-gate indicate the substrate-side electrodes. When a substrate of the N-FETs PD1, PD2, PG1 and PG2, for example, is a P-type semiconductor well region (semiconductor region), the terminal In will be constituted by an electrode ohmically connected to the P-type well region. Similarly, a substrate of the P-FETs PU1 and PU2, for example, is a N-type semiconductor well region (semiconductor region), the terminal Tp will be constituted by an electrode ohmically connected to the N-type well region.

Here, the N-FETs PD1 and PD2 can be regarded as FETs for drivers, the P-FETs PU1 and PU2 can be regarded as FETs for loads, and the N-FETs PG1 and PG2 can be regarded as FETs for transfers. When the word line WL is set to the high level, the transfer FETs PG1 and PG2 are turned on, and data is transmitted and received between the bit lines DL and/DL and the latch circuits in the memory cells S_CL.

In the first embodiment, the test pattern T_CL arranged in the TEG circuit TG has a configuration similar to that of the memory cell S_CL as described above. That is, the test pattern T_CL also has the N-FETs PD1, PD2, PG1, and PG2 and the P-FETs PU1 and PU2 illustrated in FIG. 4.

### Hi-K Disappearance

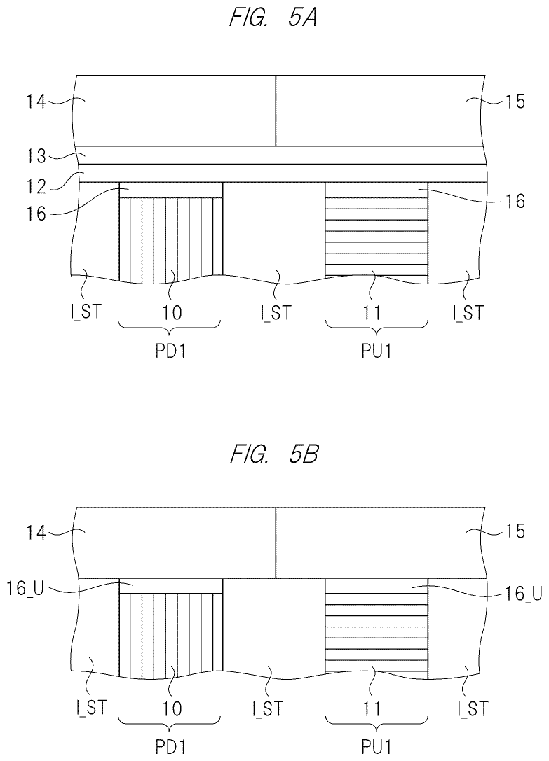

FIGS. 5A and 5B are schematic cross-sectional views for explaining a semiconductor device according to the first embodiment. FIGS. 5A and 5B illustrate cross-sectional views of the drive-use FET (N-FET PD1) and the load-use FET (P-FET PU1) shown in FIG. 4. Here, FIG. 5A illustrates a state in which no Hi-K disappearance has occurred, and FIG. 5B illustrates a state in which a Hi-K disappearance has occurred.

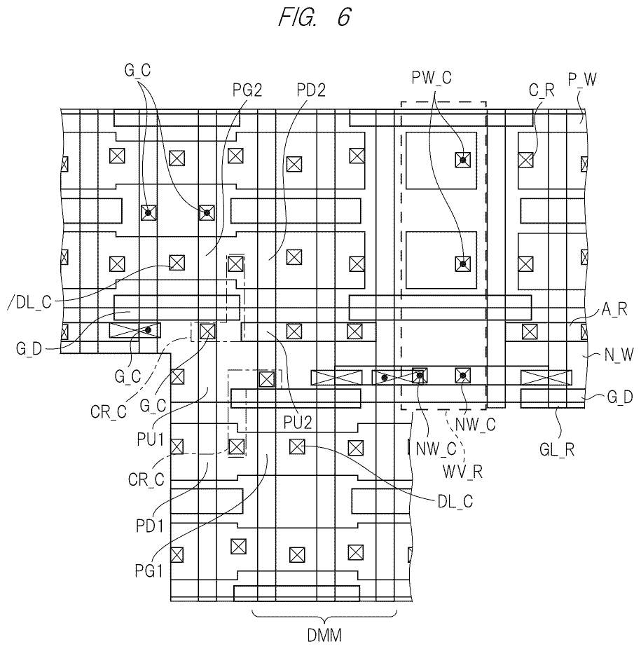

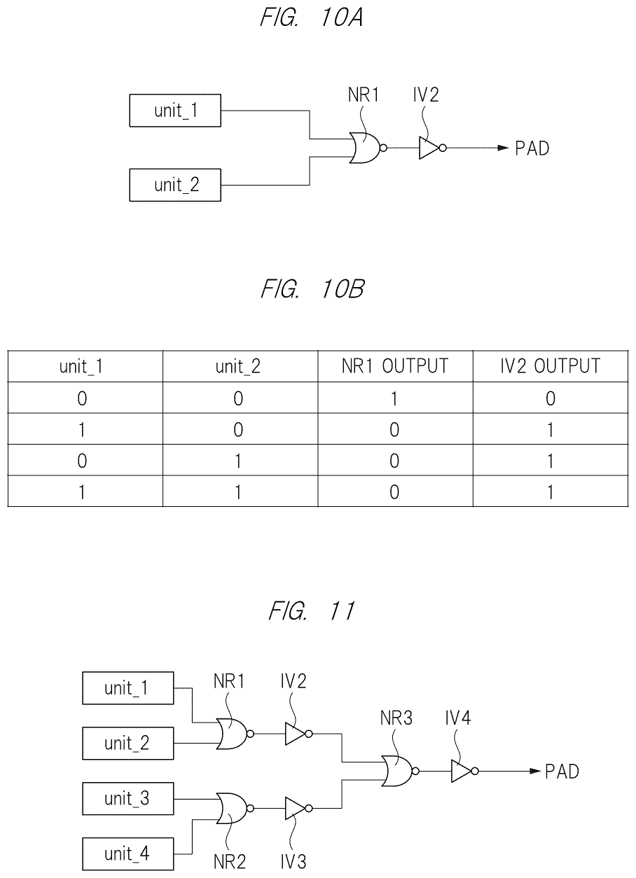

In FIGS. 5A and 5B, 10 indicates a P-type semiconductor region where the N-FET PD1 is formed, 11 indicates an N-type semiconductor region where the P-FET PU1 is formed. I_ST is an element isolation region for separating the P-type semiconductor region 10 and the N-type semiconductor region 11. The isolation regions I_ST are not particularly limited, but are formed by using a well-known STI (Shallow Trench Isolation) technique. The P-type semiconductor region 10 and the N-type semiconductor region 11 correspond to the P-type well region P_W and the N-type well region N_W in FIG. 6, which will be described later.

In FIG. 5A, a reference numeral 16 denotes a silicon oxide film of an intermediate layer formed on the P-type semiconductor region 10 and the N-type semiconductor region 11, which are activation regions, before forming the hafnium oxide film 12. A reference numeral 13 indicates a titanium nitride layer laminated on top of the hafnium oxide film 12. Also, reference numerals 14 and 15 indicate the metal constituting the gate electrode of the N-FET PD1 and the P-FET PU1. Metals 14 and 15 are formed of different metals (N-FET metal 14, P-FET metal 15) to be suitable for N-FET and P-FET. By using a gate insulating film of Hi-K, it is possible to reduce the gate leakage current flowing between, through the gate insulating film, the gate electrode (metal 14, 15) and the P-type semiconductor region 10 and the N-type semiconductor region 11.

When a Hi-K disappearance occurs, as illustrated in FIG. 5B, the hafnium oxide film 12, the titanium nitride layer 13 and the silicon oxide film 16 disappear, so that a new silicon oxide film 16_U is formed on the activation area. Since the hafnium oxide film 12 and the titanium nitride layer 13 disappear, the gate leakage current increases, and the circuit block such as the memory cell S_CL may not operate normally. Incidentally, even if a Hi-K disappearance occurs, since the silicon oxide film 16_U is formed between the gate electrode and the P-type semiconductor region 10 and the N-type semiconductor region 11, the increase of the gate leakage current is suppressed, and it may operate as a FET. However, in this case, the characteristics of the FET deteriorate and the characteristics of the circuit block also deteriorate

[symbol]

[symbol]

You will be.

### Hi-K Disappearance Detection

In the first embodiment, a circuit for detecting Hi-K disappearance is arranged in the TEG circuit TG (FIG. 3), and Hi-K disappearance can be detected in the WAT process S2 (FIG. 2).

As described above, the TEG circuit TG according to the first embodiment includes the test pattern T_CL having a configuration similar to that of the memory cell S_CL, and the logic circuit LG connected to the test pattern T_CL.

FIG. 6 is a plan view illustrating a configuration of a test pattern according to the first embodiment. The test pattern T_CL includes a FET corresponding to the FET comprising the memory cell S_CL (FIG. 4) illustrated in FIG. 4. In FIG. 6, the same reference numerals as those used in FIG. 4 are attached to the gate electrode portion of the FET. That is, in FIG. 6, reference numerals PD1, PD2, PG1, PG2, PU1 and PU2 denote the gate electrode portions of the corresponding FETs PD1, PD2, PG1, PG2, and PU1 and gate electrode portions of the corresponding PU2. In FIG. 6, P_W indicates a P-type well region formed on the semiconductor substrate (first semiconductor region), N_W indicates the N-type well region formed on the same semiconductor substrate (semiconductor region). In FIG. 6, a region filled with thin oblique lines, for example, a region A_R indicates an active semiconductor region formed in the P-type well region P_W and the N-type well region N_W. The active semiconductor region A_R is a semiconductor region isolated by an element isolation region I_ST, for example, as in the semiconductor regions 10 and 11 illustrated in FIGS. 5A and 5B. In FIG. 6, the area GL_R filled with dots indicates a gate wiring layer forming a gate electrode of the FET, the area G_D filled with a thin diagonal line and a thick diagonal line indicates a cut region for dividing the gate wiring layer GL_R. For example, the gate interconnection layers GL_R of the gate electrodes constituting the transferring FET PG1, PG2 are cut in the cut regions G_D. The area C_R marked with an X indicates the contact area.

In FIG. 6, a region WV_R surrounded by a broken line indicates a voltage fixing region for supplying a predetermined voltage to the P-type well region P_W and the N-type well region N_W. That is, by supplying a predetermined voltage to the contact region C_R formed in the voltage fixing region WV_R, the voltages of the P-type well region P_W and the N-type well region N_W are set. The contact region C_R formed in the voltage fixing region WV_R can be regarded as the terminals In and Tp shown in the memory cell S_CL shown in FIG. 4.

In FIG. 6, in a portion where the gate wiring layer GL_R and the active semiconductor region A_R intersect, an FET is configured. That is, a portion where the gate wiring layer GL_R and the active semiconductor region A_R overlap with each other has the structure shown in FIG. 5A. The overlapped portion, the gate insulating film of Hi-K is formed. Also, a portion of the active semiconductor region adjacent to the overlapped portion becomes the source region and the drain region of the FET.

In the first embodiment, and the leakage (gate leakage) current flowing between the well region (P-type well region P_W, N-type well region N_W) and the gate electrode of the FET having a source region and a drain region are formed in the well region is measured, and a detection to know whether Hi-K disappearance occurs is performed. In FIG. 6, as FETs for measuring the gate leakage current, the case of using transfer FETs PG1 and PG2 is shown. That is, in FIG. 6, the contact region C_R is formed in the gate interconnection layer (first electrode) GL_R for the gate electrode of the transfer FET PG2, the electrode (terminal) G_C is connected to the contact region C_R, and the electrode G_C is connected to the gate electrode of the transfer FET PG2. An electrode (terminal) PW_C is connected to the contact region C_R formed in the voltage fixing region WV_R, and the electrode PW_C is connected to the well region. Each of the electrodes G_C and PW_C is connected to a metal wiring for measurement (not shown). When measuring the gate leakage current, the gate electrode of the transfer FET PG, for example, −1 (V) or more voltage is applied, and the voltage of 0 (V) is applied to the P-type well region P_W.

To draw the metal wiring for measurement, in FIG. 6, and a dummy DMM three gate wiring layer from the voltage fixed region WV_R. That is, the gate wiring layer disposed at a position apart from the voltage fixed region WV_R three gate wiring layer (dummy DMM) min or more, is used to measure the gate leakage current.

Although the transfer FET PG2 is used here as an example of measuring the gate leakage current, the transfer FET PG1 may be used, or both transfer FETs may be used as an example of measuring the gate leakage current.

When the memory cell S_CL is formed by FETs PU1, PU2, PD1, PD2, PG1 and PG2 shown in FIG. 6, the power supply wirings (power supply voltage Vdd and grounding voltage GND), the word lines WL and the bit lines DL and/DL, which are not illustrated in FIG. 6, are connected to predetermined regions of the FETs by contact regions. For example, a source region or a drain region constituting a transfer FETs PG1 and PG2 is connected to bit lines DL and/DL (not illustrated) by contact regions denoted by reference numerals DL_C and/DL_C. Furthermore, a cross-connection (cross-connection of the inverter IV1, IV2 of FIG. 4) is performed by the wires indicated by the chain line CR_C.

On the other hand, in the test pattern T_CL for measuring the gate leakage current, FETs PU1, PU2, PD1, PD2, PG1 and PG2 are not connected to the power supply line, the word line WL, and the bit lines DL and/DL (not shown). The cross connection is not performed by the wiring CR_C. Instead, as described above, the electrode G_C and the electrode PW_C are connected to a metal wiring for measurement (not shown).

### Reference Resistance

A gate leakage current is the current flowing through the gate leakage resistance (measurement resistance) present between the gate electrode and the well region. In the first embodiment, the occurrence of Hi-K disappearance is detected from the resistance of the gate leakage resistance. In the first embodiment, a reference resistance is used to measure the resistance of the gate leakage resistance.

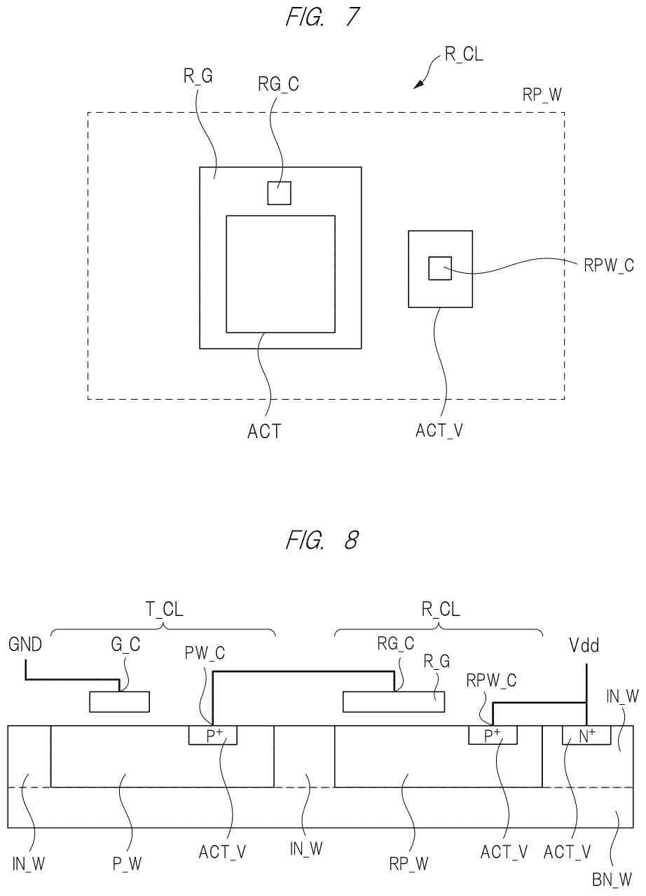

Next, reference resistances will be described with reference to the drawings. FIG. 7 is a schematic plan view illustrating a configuration of a reference resistance according to the first embodiment. Further, FIG. 8 is a schematic cross-sectional view illustrating the relationship between the reference resistance and the test pattern according to the first embodiment.

In FIG. 7, R_CL represents a reference resistance. FIG. 7 illustrates a reference resistance R_CL corresponding to the gate leakage resistance of the P-type well region P_W. As shown in FIG. 8, the P-type well region P_W and the P-type well region RP_W for the reference resistance R_CL are formed on the same semiconductor substrate. In FIG. 8, the semiconductor substrate includes a common bottom N-type well region BN_W. A P-type well region P_W forming the test pattern T_CL, between the P-type well region RP_W forming the reference resistance R_CL, N-type well region IN_W for separation is formed.

As shown in FIGS. 7 and 8, the reference resistance R_CL includes a gate wiring layer R_G formed on the P-type well region RP_W. A gate wiring layer R_G, as illustrated in FIG. 7, is formed so as to cover the active region ACT of the P-type well region RP_W, between the gate wiring layer R_G and the P-type well region RP_W, the gate insulating film of Hi-K (hafnium oxide film, a titanium nitride layer stacked thereon) is interposed. That is, in the active region ACT, the gate insulating film of Hi-K is laminated on the P-type well region RP_W, further thereon, the gate wiring layer R_G is stacked.

The gate insulating film of Hi-K in the reference resistance R_CL (second insulating film) is the same as the gate insulating film of the transfer FET PG2 (first insulating film), the area when viewed in a plan view, the second insulating film is larger than the first insulating film. In other words, when viewed in a plan view, towards the area of the semiconductor region covered by the second insulating film in the second semiconductor region RP_W is larger than the area of the semiconductor region covered by the first insulating film in the first semiconductor region P_W.

The resistance between the P-type well region RP_W and the gate wiring layer R_G becomes the reference resistance R_CL. When viewed in plan view, the area of the gate wiring layer R_G of the reference resistance R_CL is larger than the gate electrode of the transfer FET PG2 formed by the gate wiring layer GL_R, by the source region and the drain region is not formed, it is possible to prevent the occurrence of Hi-K disappearance. Since Hi-K disappearance does not occur, the reference resistance R_CL has a stable resistance that does not depend on Hi-K disappearance. The electrode (terminal) RG_C connected to the gate-wiring layer (second electrode) R_G serves as one terminal of the reference resistance R_CL, and the electrode (terminal) RPW_C connected to P+ semiconductor region (active region) ACT_V formed in the P-type well region RP_W serves as the other terminal of the reference resistance R_CL.

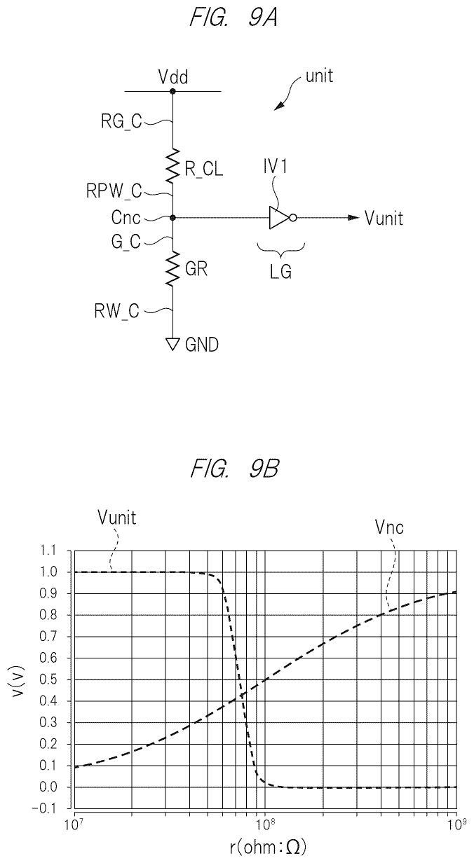

As will be described later with reference to FIG. 9, as shown in FIG. 8, a P+ type active region ACT_V is formed in the P-type well region P_W constituting the test pattern T_CL, and is connected to the gate-wiring layers R_G by the electrodes PW_C illustrated in FIG. 6. Further, the gate electrode of the transfer FET PG2 is connected to the ground voltage GND by the electrode G_C. Further, a P+ type active region ACT_V is formed in the P-type well region RP_W forming the reference resistance R_CL, and is connected to the power supply voltage Vdd by the polarity RPW_C. As a result, the potentials of the gate interconnection layers R_G of the reference resistances R_CL and the gate electrodes of the transferring FET PG2 are lower than the potentials of the P-type well regions RP_W and P_W. As a result, the P-type well regions RP_W and P_W, the bottom N-type well BN_W, and the isolation N-type well region IN_W are in a reverse bias state, and a forward current is prevented from flowing.

### TEG Circuit

FIG. 9 is a diagram for explaining a TEG circuit according to the first embodiment. Here, FIG. 9A is a circuit diagram illustrating a configuration of a unit circuit included in the TEG circuit TG. Further, FIG. 9B is a waveform diagram illustrating the operation of the unit circuit.

In the first embodiment, one unit circuit unit is configured by the test pattern T_CL the reference resistance R_CL illustrated in FIGS. 7 and 8, and the logic circuit LG illustrated in FIG. 3.

In the unit circuit unit, between the power supply voltage Vdd and the ground voltage GND, a reference resistance R CL and the gate leakage resistance GR are connected in series. Specifically, between the electrode PW_C connected to the P-type well region P_W shown in FIGS. 7 and 8 and the electrode G_C connected to the gate interconnection layers of the transfer FETs (e.g., PG2), a single gate leakage resistance (a single gate leakage resistance) is used, and the single gate leakage resistances in the plurality of test patterns T_CL are connected in parallel and used as the gate leakage resistance GR.

That is, the electrodes G_C of the gate interconnection layers of the transferring FET PG2 in the plurality of test patterns T_CL are connected to each other, and the resistance between the electrodes G_C and the electrodes PW_C of the P-type well regions P_W is the gate leakage resistance GR. Of course, the electrode G_C of the gate wiring layer of the transfer FET PG1 may be connected to the electrode G_C of the gate wiring layer of the transfer FET PG2. Thus, the single gate leakage resistance between the electrode G_C and the P-type well region P_W of the gate interconnection layer of the transfer FET PG1 will also be connected in parallel.

The electrode G_C of the gate leakage resistance GR is connected to the ground voltage GND, the electrode PW_C is connected to the electrode RG_C of the reference resistance R_CL, and the electrode RPW_C of the reference resistance R_CL is connected to the power supply voltage Vdd.

The connection node Cnc between the electrode PW_C and the electrode RG_C are connected to the input of the inverter IV1, and the output of the inverter IV1 becomes the unit output Vunit. Although not particularly limited, the inverter IV corresponds to the logic circuit LG illustrated in FIG. 3, and the unit output Vunit is supplied to the pad PAD illustrated in FIG. 3. In FIG. 9, the logic circuit LG is regarded as the first logic circuit.

In FIG. 9B, the horizontal axis indicates the resistance value of the gate leakage resistance GR, the vertical axis indicates the voltage. Here, it is assumed that the power supply voltage Vdd is 1 (V) and the resistance value of the reference resistance R_CL is 100 (MΩ). Further, the gate leakage resistance GR is s constituted by single gate leakage resistances are connected to be 100 pieces in parallel, the resistance value, when Hi-K disappearance will be described later has not occurred, it is 1 (GΩ). In contrast, when Hi-K disappearance occurs, the resistance of the gate leakage resistance GR changes from 1 (GΩ) to 10 (MΩ). As shown in FIG. 9B, when Hi-K disappearance does not occur, the intermediate potential Vnc at the connecting node Cnc rises, and when Hi-K disappearance occurs, the intermediate potential Vnc falls toward 0 (V). When the intermediate potential Vnc exceeds the logical value (about 0.4 (V)) of the inverters IV1, the unit output Vunit changes from 1 (V) to about 0 (V), and when the intermediate potential Vnc drops below the logical value (about 0.4 (V)), the unit output Vunit changes from about 0 (V) to 1 (V). That is, if a Hi-K disappearance occurs, the logical value of the output from the unit circuit unit will change from “0” to “1”. In the WAT step S2 (FIG. 2), by measuring the potential of the pad PAD of the TEG circuitry, it can be determined in the determination step S3 (FIG. 2) whether or not a Hi-K disappearance has occurred easily.

In the first embodiment, using the transfer FETs (PG1, PG2), and measures the gate leakage current flowing between the gate electrode and the P-type well region P_W. Therefore, whether or not Hi-K disappearance has occurred in the driver-use FET PD using the P-type well regions P_W can also be detected in the WAT process. In addition, with respect to the load FET PU for which the gate leakage current is not measured, for example, by connecting the cross-connection wirings (CR_C) shown in FIG. 6 also in the test pattern T_CL, when an abnormality occurs in the gate leakage current in the load FET PU, the gate leakage current of the cross-connected driver FETs also becomes abnormal, so that the abnormality can be detected.

Here, the case has been described in which the resistance value of the reference resistance R_CL is set to 1/10 of the value of the gate leakage resistance GR when no Hi-K disappearance occurs, but the resistance value of the reference resistance R_CL is not limited to this case.

### First Modification Example

FIG. 10 is a diagram for explaining a TEG circuit according to a first modification example of the first embodiment. Here, FIG. 10A is a block diagram illustrating the configuration of the TEG circuit TG, and FIG. 10B is a logic value table illustrating the operation of FIG. 10A.

The TEG circuit TG according to the first modification includes two unit circuit units (unit_1 and unit_2) shown in FIG. 9A. Further, the logic circuit LG includes an output from the unit circuit unit unit_1, and a NOR circuit NR1 and the output from the unit circuit unit_2 is input, and an inverter IV2 output of the NOR circuit NR1 is supplied. The power of this inverter IV2 is fed into the pad-PAD (FIG. 3).

As shown in FIG. 10B, when at least one of the unit circuits unit_1 and unit_2 output a logic value “1” indicating Hi-K disappearance, the output of the NOR circuit NR1 becomes “0”, and the output of the inverters IV2 becomes a logic value “1” indicating Hi-K disappearance.

### Second Modification Example

FIG. 11 is a block diagram illustrating a configuration of a TEG circuit according to a second modification example of the first embodiment. In the second modification example, illustrating an example of further increasing the number of unit circuits.

In the second modification example, unit circuits unit_3 and unit_4, a NOR circuit NR2, NR3, and inverters IV3, IV4 are added to the first modification example. When at least one of the unit circuits unit_1 to unit_4 outputs a logic value “1” indicating that Hi-K is disappeared, at least one of the NOR circuits NR1 and NR2 outputs a logic value “0”, and at least one of the inverters IV2 and IV3 outputs a logic value “1”. Consequently, the output of the NOR circuit NR3 becomes the logical value “0”, and the inverter IV4 outputs the logical value “1” indicating the occurrence of Hi-K disappearance to the pad PAD (FIG. 3).

In FIG. 11, an example of providing a NOR circuit and an inverter for the two unit circuits, but not limited thereto. For example, a NOR circuit and an inverter may be provided for three or more unit circuits. Referring to FIG. 11, the NOR circuits NR1 and NR2 and the inverters IV2 are IV3 are removed, and the NOR circuit NR3 has 4 inputs. Outputs of the unit circuits unit_1 to unit_4 are supplied to the NOR circuit NR3. By making the NOR circuit 3 have 4 inputs, it is possible to reduce the number of NOR circuits and inverters.

Incidentally, in the first and second modification examples, the inverter to which the signal from the unit circuit unit is supplied, the logic circuit constituted by a NOR circuit or the like is regarded as a second logic circuit.

According to the first and second modification examples, using more gate leakage resistance, it is possible to detect the occurrence of Hi-K disappearance, it is possible to improve the detection accuracy.

In FIGS. 7 and 8, the conductivity type of the well region constituting the reference resistance R_CL, which is the same as the conductivity type of the well region for measuring the gate leakage current, it may be a conductivity type on the opposite side (N-type). In this case, the reference resistance formed in the N-type well region, so that the unit circuit unit is constituted by the gate leakage resistance GR formed in the P-type well region.

Further, the reference resistance R_CL may be used a gate electrode of the FET and the source region and the drain region of the FET is formed well region. In this case, the source region and the drain region may be fixed to a predetermined voltage.

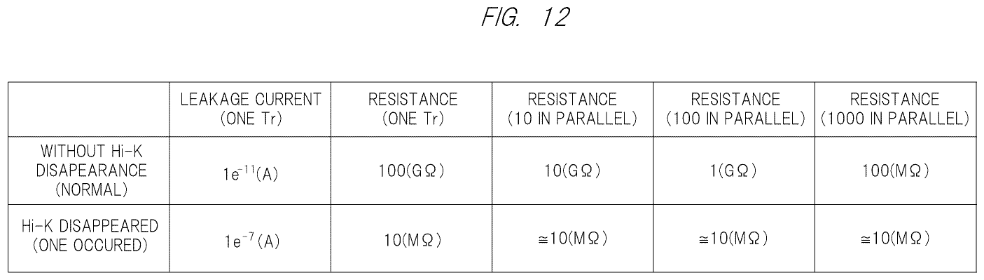

FIG. 12 is a diagram for explaining a gate leakage current and a gate leakage resistance according to the first embodiment.

When a Hi-K disappearance does not occur normally, the gate leakage current of one FET (1Tr) is about 1e⁻¹¹ (A), and the resistivity of the single gate leakage resistance at that time is about 100 (GΩ). On the other hand, when Hi-K disappearance occurs, the gate leakage current of one FET (1Tr) becomes about 1e⁻⁷ (A), and the resistance of the single gate leakage resistance at that time becomes about 10 (MΩ). As described above, by connecting the unit gate leakage resistance (unit measurement resistance) in parallel, the resistance value of the gate leakage resistance GR can be changed as shown in FIG. 12, in the WAT step, so as to have a suitable sensitivity, and it is sufficient to set the number of unit gate leakage resistance to be connected in parallel.

Increasing the number of unit gate leakage resistances to be connected in parallel will also increase the current flowing in the TEG circuit, since the gate leakage current when normal Hi-K is not generated is small, there is no problem.

### Adoption of Logic Circuit LG

As illustrated in FIG. 12, depending on whether or not Hi-K disappearance has occurred, the value of the flow gate leak current is 4 digits (1e⁻⁷ (A) and 1e⁻¹¹ (A)) different. In order to detect whether or not Hi-K disappearance has occurred in the WAT production process, the four-digit difference is measured.

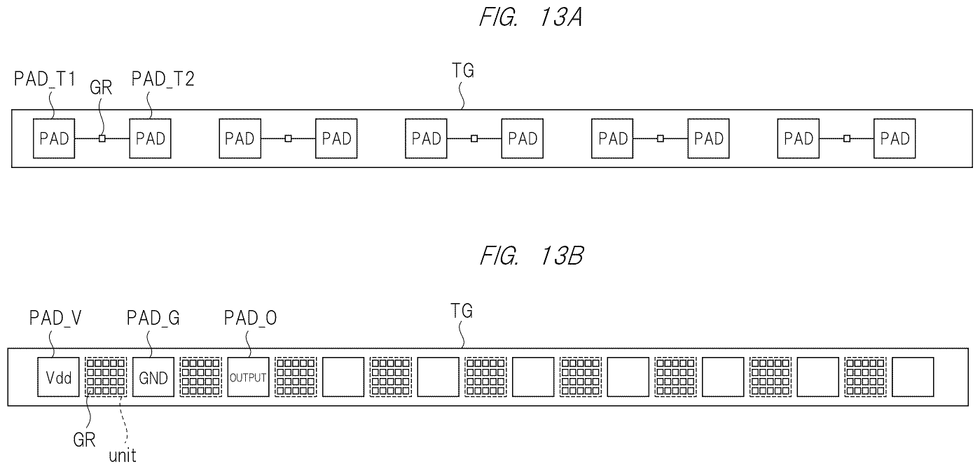

FIG. 13 is a diagram for explaining an effect according to the first embodiment.

In order to measure a four-digit current difference, for example, a configuration as shown in FIG. 13A is considered. That is, a plurality of (five in FIG. 13A) TEG circuits TG are provided with the gate leakage resistance GR and the pads PAD_T1 and PAD_T2 connected to both ends of the gate leakage resistance GR as one unit. Here, the gate leakage resistance GR is assumed that 100 unit gate leakage resistances are connected in parallel as an example. By measuring the current flowing between the pad PAD_T1 and the pad PAD_T2, it is possible to measure a current difference of four orders of magnitude. However, even if 10 pads PAD_T1 and PAD_T2 are provided in the TEG circuit TG, the number of unit gate leakage resistances that can be measured is about 500 (100×5).

On the other hand, according to the first embodiment, the structure can be configured as shown in FIG. 13B. In FIG. 13B, PAD_V indicates a power supply pad to which the power supply voltage Vdd is supplied, PAD_G indicates a ground pad to which the ground voltage GND is supplied, and PAD_O indicates an output pad to which the output of the unit circuitry unit is supplied.

In the example shown in FIG. 13B, the unit circuits unit each includes 20 gate leakage resistance GR 100 unit gate leakage resistances are connected in parallel. Further, the unit circuit unit includes a reference resistance R_CL (not shown) (FIG. 9) and the logic circuit LG. The gate leakage resistance GR and the reference resistance R_CL are connected between the power supply pad PAD_V and the ground pad PAD_G, and the output of the logic circuit LG, which changes in accordance with the value of the gate leakage resistance GR, is supplied to the output pad PAD_O. When 10 pads are provided in the TEG circuit TG as in FIG. 13A, according to the first embodiment, as understood from FIG. 13B, 18,000 (20×9×100) gate leakage resistances GR can be provided in the TEG circuit TG. If abnormal gate leakage current flows in any of the 18000 gate leakage resistances, since the voltage of the output pad PAD_O is changed, it is possible to detect the abnormality.

That is, according to the first embodiment, it is possible to improve the detection accuracy while suppressing an increase in the area occupied by the TEG circuit TG.

Further, in the first embodiment, since the gate leakage current is converted into a digital logical value by the logic circuit LG, Hi-K disappearance can be easily detected in the WAT step S2 and the determination step S3.

Incidentally, the gate electrode of the load FET PU1 (PU2) and the driver FET PD1 (PD2) by cross-connection, connected to the drain region of the load FET PU2 (PU1) and the driver FET PD2 (PD1, when using the driver FET or/and the load FET as a gate leakage resistance, the gate electrode is connected it is required to consider the leakage current flowing from the drain region.

Although an example in which a configuration similar to that of the memory cell S_CL is used has been described as the test pattern T_CL, a test pattern having a circuit configuration different from that of the memory cell S_CL (e.g., a logic circuit or a FET connected in parallel with a gate electrode having a small ratio of length to width) may be used. However, by using a test pattern T_CL similar to the memory cell S_CL, Hi-K disappearance occurring in the memory cell S_CL can be detected more accurately.

The gate insulating film of Hi-K of the reference resistance R_CL is the same as the gate insulating film of the memory cell S_CL and the test pattern T_CL, and is manufactured by the same process. When the thickness of, for example, the gate insulating film of Hi-K of the memory cell S_CL and the test pattern T_CL fluctuates due to process fluctuations in the manufacturing process, Hi-K gate insulating film of the reference resistance R_CL fluctuates in the same manner, and the ratio between the reference resistance R_CL and the gate leakage resistance can be maintained.

### Second Embodiment

In a second embodiment and a third embodiment to be described next, the incidence of Hi-K disappearance in the test pattern T_CL is made higher than that in the memory cell S_CL. A gate leakage resistance of the test pattern in which the probability of occurrence of Hi-K disappearance is increased is used as a single gate leakage resistance described in FIG. 9. By increasing the probability of occurrence of Hi-K disappearance in the test pattern T_CL, it is possible to increase the sensitivity of detecting occurrence of Hi-K disappearance, for example, when there is a process variation.

### Causes of Hi-K Disappearance

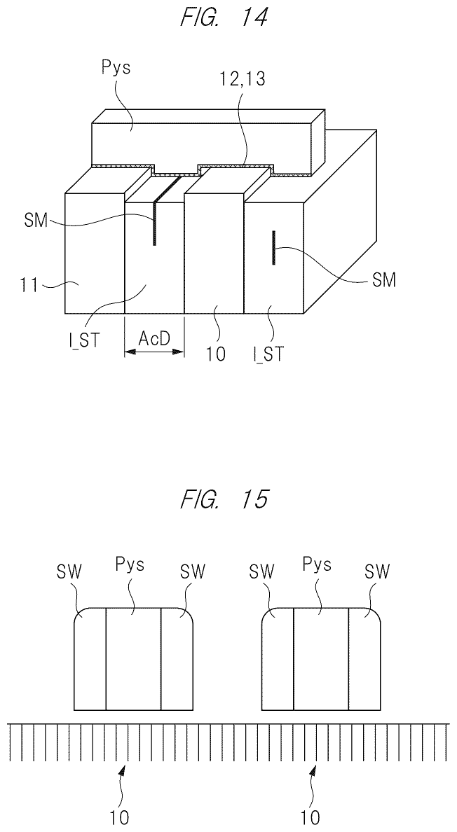

First, a cause of Hi-K disappearance found by the present inventors will be described with reference to the drawings. Here, two causes will be explained. FIGS. 14 and 15 are diagrams for explaining the manufacture of the semiconductor device according to the second embodiment and the third embodiment.

### STI-Seam (Seam)

FIG. 14 is a schematic perspective view illustrating a part of the semiconductor device according to the second embodiment. FIG. 14 is similar to FIG. 5. First, an outline of a manufacturing process of FET PD1 for drivers and FET PU1 for loads shown in FIG. 5 will be described.

A P-type semiconductor region 10, an N-type semiconductor region 11, and an element isolation region I_ST are formed, and a hafnium oxide film 12 and a titanium nitride layer 13 are formed thereon. On the hafnium oxide film 12 and the titanium nitride layer 13, a polysilicon layer Pys is formed, and an impurity implantation (hereinafter, referred to as SD implantation) for forming a source region and a drain region is performed using this polysilicon layer Pys as a mask. Thereafter, the polysilicon layer Pys are removed, the gate wiring layer serving as a gate electrode is formed.

When the element isolation region I_ST is formed, a seam SM as shown in FIG. 14 is generated. In the element isolation region I_ST existing between the N-type semiconductor region 11 and the P-type semiconductor region 10, when a seam SM as shown in FIG. 14 is generated in the vicinity of the hafnium oxide film 12 and the titanium nitride layer 13, a treatment liquid such as hydrofluoric acid used in a later step melts the hafnium oxide film 12 of the seam SM portion, melts the hafnium oxide film 12 and the titanium nitride layer 13 below the gate electrode connected thereto, and Hi-K disappearance occurs.

### Sidewall (Side Wall)

When describing the SD injection with reference to FIG. 15, in an SD injection, using a polysilicon layer Pys corresponding to the gate electrode and a sidewall SW (silicon nitride layer, etc.) as a mask, into the P-type semiconductor region 10, implantation of an impurity is performed. The silicon nitride layer of the sidewall SW is oxidized by ashing of the SD implantation, and this oxidized portion is melted and thinned by wet treatment performed later. Therefore, as the number of SD injections increases, the sidewall SW becomes thinner.

When the sidewall SW becomes thinner, the distance between the outside of the sidewall SW and the hafnium oxide film 12 under the gate electrode and the titanium nitride layer 13 becomes shorter, and when the seam SM as illustrated in FIG. 14 is present, hydrofluoric acid or the like through the seam SM easily infiltrates. In addition, not only the seam SM but also other causes such as defects in the sidewall SW tend to cause infiltration. Thus, the hafnium oxide film 12 and the titanium nitride layer 13 on the lower side of the polysilicon layer Pys disappear by the impregnated solvent, and a Hi-K disappearance occurs.

In the second embodiment, the causes of <<STI-seam>> are used. That is, in the second embodiment, the active space in the test pattern T_CL is narrower than the memory cell S_CL. Referring to FIG. 14, in FIG. 14, a space corresponding to the width of the element isolation region I_ST for isolating the semiconductor regions from each other is illustrated as an inter-active space AcD. By narrowing the inter-active space AcD, a seam SM is easily formed so as to disappear the hafnium oxide film 12 and the titanium nitride layer 13 under the gate electrode. As a result, in the test pattern T_CL, it is possible to increase the incidence of Hi-K disappearance, and it is possible to increase the sensitivity of detecting a Hi-K disappearance.

### Third Embodiment

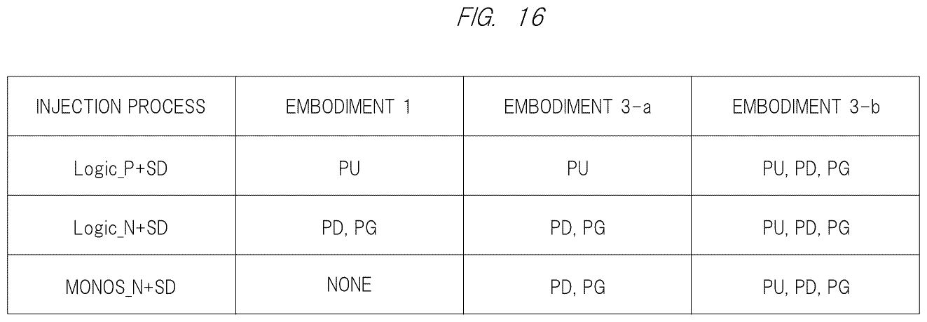

In a third embodiment, the cause of <<STI-seam>> is used. That is, in the test pattern T_CL, the number of SD injection is increased compared with the memory cell S_CL. FIG. 16 is a diagram for explaining a method of manufacturing a semiconductor device according to the third embodiment.

In FIG. 16, the injection step illustrates a step of performing SD injection in the manufacturing process. Logic_P+SD indicates the step of SD implantation into the source and drain regions of the P-channel FET in the circuit block PR (FIG. 3) and SRAM circuit MM_S (FIG. 3), and Logic_N+SD indicates the step of SD implantation into the source and drain regions of the N-channel FET. MONOS_N+SD represents a step of implanting SD into the source region and the drain region of an N-channel MONOS transistor.

For example, in the first embodiment, SD implantation is performed into the source region and the drain region of the test pattern T_CL (FIG. 4) in the loading FET PU (PU1, PU2 of the test pattern T_CL (FIG. 6) in the Logic_P+SD process, and SD implantation is performed into the driver FET PD of the test pattern T_CL and in the source region and the drain region of the transfer FET PG in the Logic_N+SD process. At this time, SD injection is not performed for the FET of the test pattern T_CL in the MONOS_N+SD process. That is, one SD-injection is performed for each of the loading FET PU, the driver-use FET PD, and the transfer FET PG of the test pattern T_CL.

On the other hand, in the third embodiment, the number of SD injections to the FETs constituting the test pattern T_CL is increased. FIG. 16 illustrates two examples of increasing the number of SD injections.

In the first example (3-a of the third embodiment), SD implantation is also performed in the MONOS_N+SD process for the source region and the drain region of the driver FET PD and the transfer FET PG in the test pattern T_CL. That is, two SDs are injected into the driver-use FET PD and the transfer-use FET PG in the test pattern T_CL.

In the second example (3-b of the third embodiment), in the Logic_P+SD process, the Logic_N+SD process, and the MONOS_N+SD process, SD injection is performed for each of the load FET PU of the test pattern T_CL, the driver FET PD, and the transfer FET PG. At this time, an impurity suitable for the channel type is implanted into the source region and the drain region. In the second embodiment, SD-injection is performed three times for each of the load-use FET PU, the driver-use FET PD, and the transfer-use FET PG of the test pattern T_CL.

That is, in the third embodiment, more than the number of implantations of impurities into the source region or/and the drain region of the FET formed in the semiconductor chip CHP, the number of implantations of impurities into the source region or/and the drain region of the FET formed in the test pattern T_CL is increased.

In the test pattern T_CL, by increasing the number of SDs implanted, overetching can be generated to increase the incidence of Hi-K disappearance, and a Hi-K disappearance can be detected more sensitively.

Since the detection sensitivity of Hi-K disappearance can be increased, a semiconductor wafer in which a slight Hi-K disappearance that cannot be detected by ordinary tests occurs can also be extracted from the semiconductor wafer. Semiconductor wafers in which minor Hi-K disappearance has occurred are feared to become malfunctioning after delivery to customers as semiconductor chips. Since a semiconductor wafer in which minor Hi-K disappearance has occurred can be easily detected in the WAT production process, it is possible to prevent semiconductor chips that are defective from being shipped to customers.

Although the invention made by the present inventors has been specifically described based on the embodiment, the present invention is not limited to the embodiment described above, and it is needless to say that various modifications can be made without departing from the gist thereof. For example, in the first to third embodiments, the configuration for measuring the gate leakage current of the FET including the gate insulating film of Hi-K in order to detect the occurrence of Hi-K disappearance has been described, but the FET for measuring the gate leakage current is not limited thereto. As the gate insulating film, it may be measured gate leakage current of the FETs using a silicon oxide (SiO2) film or a silicon oxynitride (SiON) film.

What is claimed is:

1. A semiconductor wafer in which a plurality of semiconductor chips are disposed,
the semiconductor wafer comprising a test pattern including a reference resistance and a measurement resistance which is connected with the reference resistance in series and through which a leakage current flows,
wherein a voltage at a connection node between the reference resistance and the measurement resistance is measured.

2. The semiconductor wafer according to claim 1
wherein the test pattern is disposed on a scribe line for cutting the plurality of semiconductor chips from the semiconductor wafer.

3. The semiconductor wafer according to claim 2,
wherein the measurement resistance is formed by a first semiconductor region and a first electrode disposed on the first semiconductor region through an insulating layer containing a material having a dielectric constant higher than that of a silicon nitride film,
wherein the reference resistance is formed by a second semiconductor region and a second electrode disposed on the second semiconductor region through an insulating layer containing a material having a dielectric constant higher than that of the silicon nitride film.

4. The semiconductor wafer of claim 2,
wherein a plurality of semiconductor chips are cut out of the semiconductor wafer after a voltage at the connection node is measured.

5. The semiconductor wafer of claim 1,
wherein the measurement resistance includes a plurality of unit measurement resistances connected in parallel with each other, and
wherein the test pattern includes a first logic circuit connected to the connection node.

6. The semiconductor wafer of claim 5,
wherein the test pattern includes: a plurality of unit circuits; and a second logic circuit to which outputs of the plurality of unit circuits are supplied, and
each of the plurality of unit circuits includes: the reference resistance; the measurement resistance; and the first logic circuit.
